(19) United States
(12) Patent Application Publication
(10) Pub. No.: US 2006/0250832 A1
(43) Pub. Date: Nov. 9, 2006

(54) System for converting input voltage in memory card

(75) Inventors: Chia-Ching Su, Taipei City (TW); Tai-Jung Huang, Taipei (TW)

Correspondence Address: LOWE HAUPTMAN BERNER, LLP, 1700 DIAGONAL ROAD, SUITE 300, ALEXANDRIA, VA, 22314, US

(73) Assignee: SILICON POWER COMPUTER & COMMUNICATIONS, INC., Taipei (TW)

(21) Appl. No.: 11/296,297

(22) Filed: Dec. 8, 2005

(30) Foreign Application Priority Data
May 6, 2005 (TW) 94114623

(51) Int. Cl. G11C 19/08

(52) U.S. Cl. 365/1

(57) ABSTRACT

A system in the memory card for converting the input voltage is used to provide the most suitable voltage for the internal devices. The input voltage from external device is limited by association and specification, so is not truly suitable to the voltage demand of the internal devices. This problem could cause the power loss and reduce aging of the internal devices. The present system convert the input voltage for the voltage demand of the internal devices by switching boost-up or step-down, so as to increase the power efficiency, the operation time and having more different choices in internal devices.

### FIELD OF THE INVENTION

The present invention relates to a switching module in the small memory card for converting the input voltage, and more particularly relates to a switching module for converting input voltage to convert the stable voltage of the external power to the suitable voltage for internal components according to the needed voltage of the internal components of the memory card.

### DESCRIPTION OF THE PRIOR ART

There are several models of the small memory cards in the market: Secure Digital card (SD card), Mini Secure Digital card (Mini MD card), Multimedia card (MMC), Reduced Size Multimedia card, Compact Flash card (CF card), Smart Media card (SM card), and Memory Stick (MS card). In addition, Secure Digital card and Multimedia card are similar in specifications and looks. Both of then are commonly used in portable electronic products such as Personal Digital Assistant (PDA), Digital Camera, Cell Phone and so on. According to small memory cards described above, AND type and NAND type flash memory are the memory components frequently used to write, rewrite and keep the data during long period of time without power.

FIG. 1 is illustrating a traditional data access and controlled structure of the memory card. According to the transmission standard of the SD card or MMC, when the data is transferred from the memory card golden finger 100 and stored in the memory chip 106, the process is to operate the data reading or writing from the main controlled chip 103. The memory card gold finger 100 is used to be the data transfer interface for the memory card and the external device (not shown). Moreover, the main controlled chip 103 is based on the controlled signal of the external device to do the operation of the data reading or writing of the memory chip 106. The memory chip 106 is used to provide data storing.

The traditional data access and controlled structure of the memory card is shown in FIG. 1. The power of the memory card is provided from the external device and the power wire is from the memory card golden finger to the connection of the main controlled chip 103 and the memory chip 106. In the traditional structure, the power is directly provided to the main controlled chip 103 and the memory chip 106 by using simple linear voltage step-down that the main reason is to save the cost of the hardware of the memory card. Because the internal space of the memory card is too small, it is hard to add a switching module for converting voltage to convert the supply voltage. Therefore, the voltage can be decreased but not to be increased, and there is some power loss because of the linear voltage step down of the power.

According to the description above, in the traditional data access and controlled structure of the memory card, the standard power of the external device is directly provided or provided to the main controlled chip 103 and the memory chip 106 after the simple linear voltage step down. However, the standard voltage cannot represent the suitable voltage for the internal electronic components. The following drawbacks will be caused: first, because the memory chip 106 of the memory card is limited by the voltage supply, the choices of the specifications of the memory chip 106 are limited. The specific memory chip 106, which can be provided in the public, is relying on the supply of the market and the production of the memory card is effect. Second, the voltage is too high or too low will affect the operation of the main controlled chip 103 and the memory chip 106. If the voltage is too low, the main controlled chip 103 and the memory card 106 cannot be worked. If the voltage is too high, the electricity is wasted. Because the power is lost and the usage time is reduced, the electronic components will be aging quickly.

According to this, it is necessary to provide a voltage converting system to improve the structure of the data access and controlled in the traditional memory card. In the limited internal space of the memory card, the suitable voltage is provided for the need of the internal components of the memory card by converting the standard input voltage of the external device.

### SUMMARY OF THE INVENTION

According to the prior art described above, the input voltage of the data access structure of the traditional memory card is not sure to provide the suitable need of the voltage for the internal components and causes a lot of drawbacks. Therefore, one of the purposes of the present invention is to provide the suitable voltage for the need of the internal components and the choices of the suitable electronic components are became more and more widely. The convenience and the efficiency for developing the product are increased.

The other purpose of the present invention is to provide a system to convert the input voltage. The efficiency of the usage of the power is increased and the electricity is saved, and the lifetime of the internal components is extended and the probability of the malfunction will be reduced.

According to the purpose described above, the present invention comprises a switching module in the small memory card for converting the input voltage. The memory card is said to comprise a switching module for converting voltage, which is to boost up and step down the need of the voltage level for the electronic components being the source of the power supply. Therefore, the electric power saving can be achieved by increasing the usage of the power, and delay the aging of the internal components and reduce the probability of the malfunction of the components.

### BRIEF DESCRIPTION OF THE DRAWINGS

FIG. 1 is a system block diagram illustrating the traditional small memory card.

FIG. 2 is a system block diagram illustrating the small memory card with voltage step-down module in one embodiment of the present invention.

FIG. 3 is a system block diagram illustrating the small memory card with voltage boost-up module in one embodiment of the present invention.

FIG. 4 is a diagram illustrating the voltage step-down module in one embodiment of the present invention.

FIG. 5 is a diagram illustrating the voltage boost-up module in another embodiment of the present invention.

### DESCRIPTION OF THE PREFERRED EMBODIMENT

Some of the detail embodiments of the present invention will be described below. However, beside the detail description, the present invention can be generally used in other embodiments.

A switching system of the memory card for converting input voltage is disclosed in the present invention. The input voltage is converted to the suitable voltage and provided for the internal components of the memory card. The specifications of the memory card in the present invention are included Secure Digital card (SD card), Mini Secure Digital card (Mini SD card), Micro Secure Digital card (Micro SD card), Multimedia card (MMC), High Speed Multimedia card (HS-MMC), Multimedia card plus (HS-MMC), Reduced Size Multimedia card (RS-MMC), High Speed Reduced Size-Multimedia card (HS RS-MMC), Multimedia card Mobile (MMC mobile), multimedia card Micro (MMC micro), Compact Flash card (CF card), Compact Flash type I card (CF type I card), Compact Flash II card (CF type II card), Smart Media card (SM card), Memory Stick (MS), MagicGate Memory Stick (MagicGate MS), Memory Stick Pro (MS Pro), MagicGate Memory Stick Pro (MagicGate MS Pro), Memory Stick Duo (MS Duo), MagicGate Memory Stick Duo (MagicGate MS Duo), Memory Stick Pro Duo (MS Pro Duo), MagicGate Memory Stick Pro Duo (MagicGate MS Pro Duo), and those memory cards had been developed or will be developed. The different of the specifications of those memory cards are changed by using the technology of the prior art.

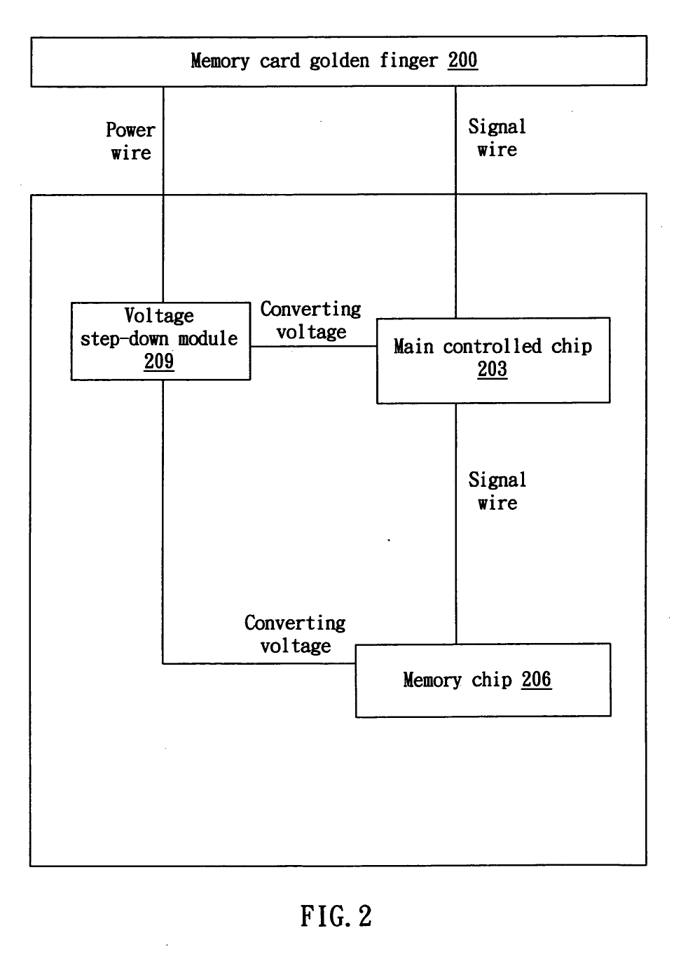

FIG. 2 is a system block diagram illustrating one of the embodiments of the present invention. A structure of the data access of the memory card with the voltage step-down module is disclosed herein. There are a memory card golden finger 200, a controlled chip 203, a memory chip 206 and a voltage step-down module 209 in this structure. By comparing the structure of the data access of the memory card in the prior art, there is another voltage step-down module 209 using the switching step-down chip to step down the external voltage-and provide voltage by the need of each component in the situation of the lost of the smallest power. According to each block of the FIG. 2, the following is the detail description of the individual functions, the transfer of the power or data, and the controlled method.

The memory card golden finger 200 is used to be the interface for the external device and the internal components. It is used to transfer the data to the external device, such as computer or personal digital assistant (PDA), after reading from the memory chip 206. On the other hand, the data is from the external device and written in the memory chip 206. The memory card golden finger 200 is electrically connected to the voltage step-down module 209 and both of them are doing power transfer. Besides, the memory golden finger 200 is electrically connected to the main controlled chip 203 and both of them are doing data transfer.

The voltage step-down module 209 is also connected to the main controlled chip 203 and the memory chip 206. The voltage step-down module 209 is received the power provided from the external device by using the power wire between the module and the memory card golden finger 209. Then, the input voltage is in the step-down procedure and output the converting voltage to the main controlled chip 203 and the memory chip 206. In the present embodiment, the voltage step-down module 209 is included a switching step-down chip. The chip is included a Pulse Width Modulator (PWM) step-down voltage or a Pulse Frequency Modulation (PFM) step-down voltage. The benefits of using the Switching Step-Down chip are to avoid the power lost by the method of the Linear voltage Step-Down and achieve the power saving by completely utilizing the receiving power. Besides, the voltage after transferring is correspond with the need of the voltage level of the main controlled chip 203 and the memory chip 206. Then the aging of the components is extended.

The main controlled chip 203 is also connected to the memory chip 206. The main controlled chip 203 will use the signal wire to transfer the data from the external device and written in the memory chip 206. Similarly, the data of the main controlled chip 203 is read from the memory chip 206 by the signal line and is transferred to the external device. The main function of the main controlled chip 203 is to transfer the controlled signal and do the operation of reading or writing to the memory chip 206. The data transfer is in between the main controlled chip 203 and the memory chip 206.

The main function of the memory chip 206 is to be the data storage. The operation of the data reading and writing in the memory chip 206 is controlled by the controlled signal of the main controlled chip 203.

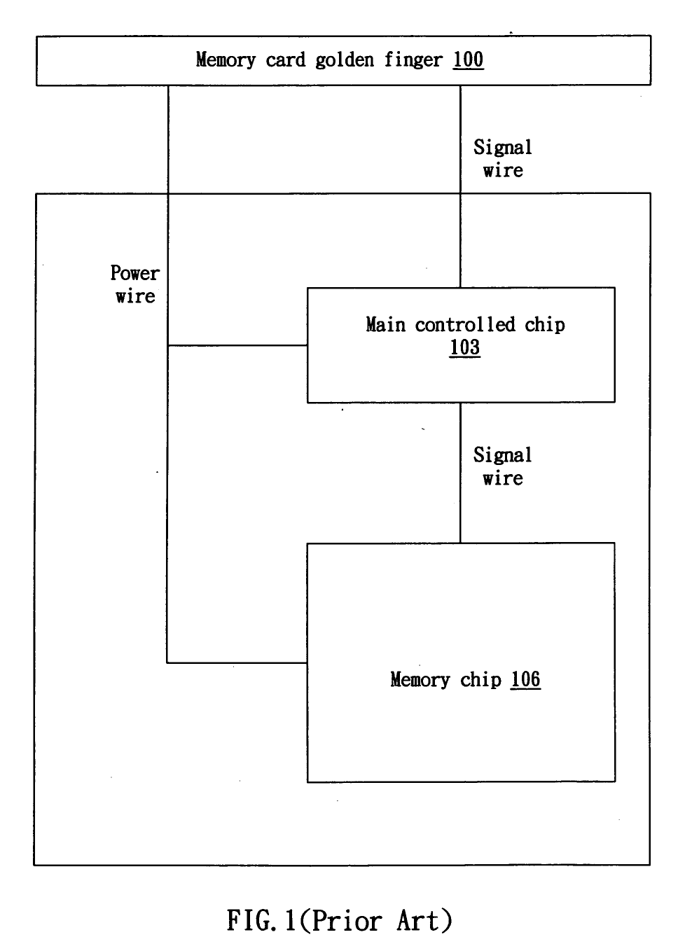

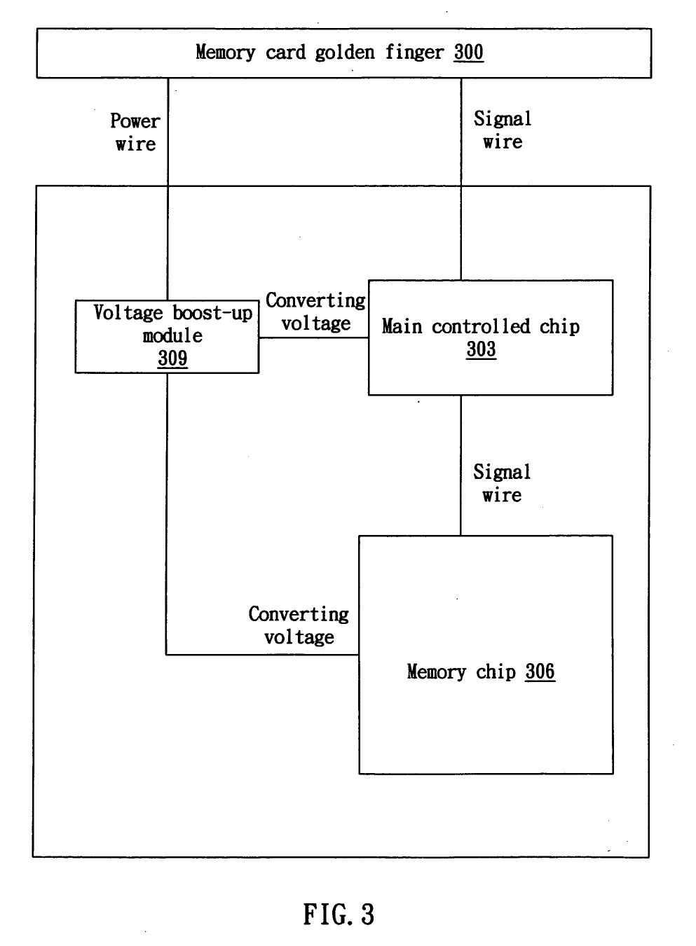

FIG. 3 is the system block diagram of another embodiment of the present invention. A structure with voltage boost-up module is used to access the data is disclosed herein. There are a memory card golden finger 300, a controlled chip 303, a memory card chip 306 and a voltage boost-up module 309 in this structure. Similarly, to compare with the prior art (FIG. 1), there is another voltage boost-up module in this embodiment of the present invention. The Switching Boost Up chip is used to boost up the external input voltage by the need of the components and then supply the voltage.

The memory card golden finger 300 is used to be an interface for the external device and the internal components. The data is read in the memory card 306 and transferred to the external device, or the data is written into the memory card 306 from the external device. The memory card golden finger 300 is electrically connected to the voltage boost-up module 309 and the power will be transferred between both of them.

The voltage boost-up module 309 is also connected to the main controlled chip 303 and the memory chip 306. The power wire in between the voltage boost-up module 309 and the memory card golden finger 300 is used to receive the power from the external device. The received input voltage is used to boost up the voltage and output the converted voltage to the main controlled chip 303 and the memory chip 306. In the present embodiment, there is a Switching Boost-Up chip used in the voltage boost-up module 309. The Switching Boost-Up chip is included a Charge Pump boost-up circuit, a Pulse Width Modulator (PWM) boost-up voltage or a Pulse Frequency Modulation (PFM) to boost-up the voltage level. After the input voltage is converted by the voltage boost-up module 309, a higher converted voltage is provided to the main controlled chip 303 and the memory chip 306. Therefore, when the main controlled chip 303 and the memory chip 306 are in choosing, there are more different components can be chosen. It is important to shorten the time in developing in today's market.

In FIG. 3, the main controlled chip 303 is also connected to the memory chip 306. The data of the main controlled chip 303 is written to the memory chip 306 from the external device by the signal wires. Similarly, the data of the main controlled chip 303 is read from the memory chip 306 and transferred to the external device by the signal wires. The main function of the main controlled chip 303 is to transfer the controlled signal, which is used to control the data reading and writing of the memory chip 306. The data transfer and access is in between memory chip 303 and the memory chip 306. The main function of the memory chip 306 is used to be the data storage. The memory chip 306 is operated by the controlled signal of the main controlled chip 303 to do the data reading and writing.

The voltage step-down module 209 (FIG. 2) and the voltage boost-up module 309 (FIG. 3) can also be replaced by the converting voltage module (not shown). There is a Switching Boost Up/Step Down circuit used in the converting voltage module. Boost Up/Step Down is represented doing boost-up or step-down respectively or at the same time. Therefore, the Switching Boost Up/Step Down circuit can do the operation of boost-up or step-down to the input voltage or do the operation of boost-up and step-down to the input voltage at the same time. Then, there is a converting voltage output to the internal components of the small memory card.

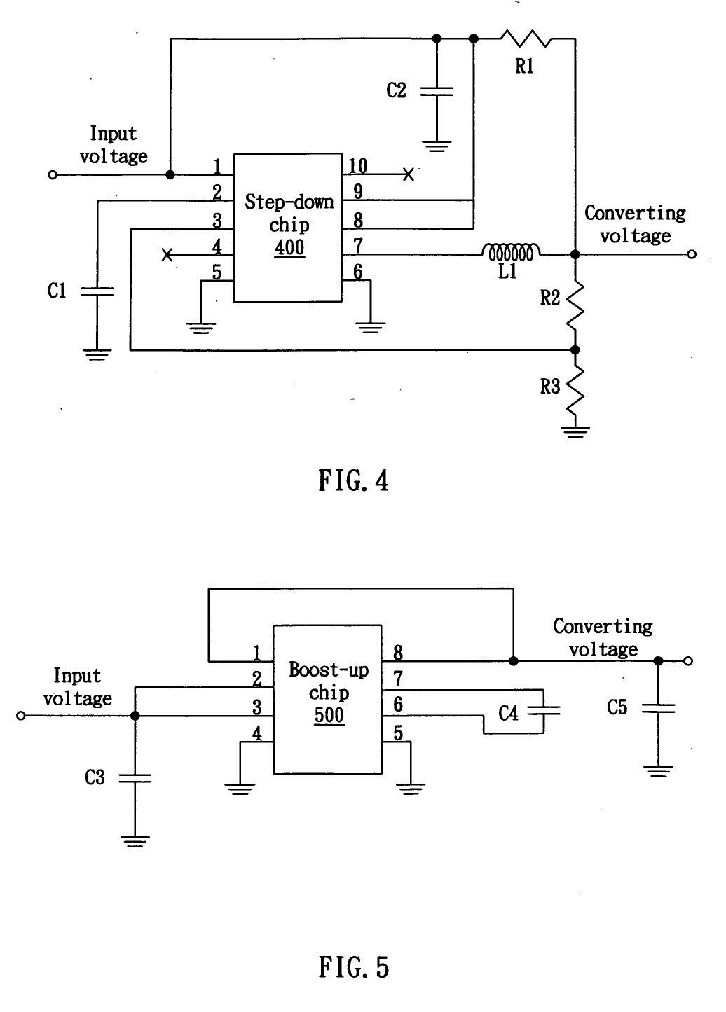

FIG. 4 is one embodiment, which is satisfied the voltage step-down module 209 in FIG. 2. The present embodiment is a voltage step-down circuit in the prior art. The creation of the present embodiment is to find compatible electronic components to achieve stepping down voltage in the limited space of the small memory card. Generally, because of the cost control of the circuit and the limited space of the small memory card, in the prior art, it is not easy to add the voltage step-down circuit or just add a simple linear step-down component. Referring to FIG. 4, a switching step-down chip 400 is the main component in the voltage step-down circuit. The function of each pins of the switching step-down chip 400 is: Pin 1 is used to receive the active signal to activate the chip. Pin 2 is used to activate the chip by the software controlling the signal. Pin 3 is used to be the feedback control, which controls the converting voltage level. Pin 4 and Pin 10 have no functions, so there is no wire connected to the circuit. Pin 5 and Pin 6 are grounded. Pin 7 is used to connect to inductance. Pin 8 and Pin 9 are connected to the power in order to operation the chip. In the present embodiment, the input voltage is connected to the Pin 1 of the voltage step-down chip 400 and connected to the capacitance C2 and the resistance R1, the other pin of the C2 is grounded. Pin 2 is connected to the capacitance C1 and the other pin of the capacitance is grounded. Pin 3 is connected in between the resistance R2 and the resistance R3. Pin 4 and Pin 10 are not connected to anything. Pin 5 and Pin 6 are grounded. Pin 7 is connected to the inductance L1 and the other pin of the L1 is connected to the resistance R1 and the resistance R2. Pin 8 and Pin 9 are short at the beginning and are connected in between the capacitance C2 and resistance R1. Resistance R1, resistance R2 and resistance R3 are connected together with series connection.

In FIG. 4, the purpose of the capacitance C1 and the capacitance C2 are used to filter and stabilize the voltage supply. The resistance R1, the resistance R2 and the resistance R3 are series connection to divide the voltage. The different pins are able to receive suitable voltage. The purpose of the inductance L1 is to stabilize the current and be the phase compatible component.

FIG. 5 is one embodiment, which is satisfied the voltage boost-up module 309 in FIG. 3. The present embodiment is a voltage boost-up circuit in the prior art. The creation of the present embodiment is to find compatible electronic components to achieve boosting up the voltage in the limited space of the small memory card. Referring to FIG. 5, a switching boost-up chip 500 is the main component in the voltage boost-up circuit. The function of each pins of the switching boost-up chip 500 is: Pin 1 is used to be the feedback control. Pin 2 is used to receive the active signal in order to activate the chip. Pin 3 is used to receive the input voltage. Pin 4 and Pin 5 are grounded. Pin 5 is connected to the negative of the capacitance. Pin 7 is used to connect to the positive of the capacitance. Pin 8 is used to output the converted voltage. In the present embodiment, the input voltage is connected to the Pin 2 and Pin 3 of the voltage boost-up chip 500 and a capacitance C3, and the other pin of the capacitance C3 is grounded. There is no connection in between Pin 2 and Pin 3. Similarly, there is no connection in between Pin 1 and Pin 8. Both of them are connected to the capacitance C5, and the other pin of the capacitance C5 is grounded. Pin 4 and Pin 5 are grounded. There is a capacitance C4 to be the connection in between Pin 6 and Pin 7. In FIG. 5, The purpose of the capacitance C3, the capacitance C4 and the capacitance C5 are to be the filter and stabilize the converted voltage supply.

The foregoing description is not intended to be exhaustive or to limit the invention to the precise forms disclosed. Obvious modifications or variations are possible in light of the above teachings. In this regard, the embodiment or embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly and legally entitled.

What is claimed is:

1. A switching system adaptable for a small memory card for converting an input voltage, comprising:
a switching voltage converting module having an input pin to receive the input voltage and out a converting voltage after switching boost up/step down converting.

2. The switching system of claim 1, wherein said system is within the small memory card.

3. The switching system of claim 1, wherein said system has one or the combination of the following components: a Pulse Width Modulation (PWM) Boost-Up circuit, a Pulse Frequency Modulation (PFM) Boost-Up circuit, a Charge Pump Boost-Up circuit, a Pulse Width Modulation Step-Down circuit, and a Pulse Frequency Modulation Step-Down circuit.

4. The switching system of claim 1, wherein said small memory card is one of the following type: Secure Digital card (SD card), Mini Secure Digital card (Mini SD card), Micro Secure Digital card (Micro SD card), Multimedia card (MMC), High Speed Multimedia card (HS-MMC), Multimedia card plus (MMCplus), Reduced Size Multimedia card (RS-MMC), High Speed Reduced Size-Multimedia card (HS RS-MMC), Multimedia card Mobile (MMC mobile), multimedia card Micro (MMC micro), Compact Flash card (CF card), Compact Flash type I card (CF type I card), Compact Flash II card (CF type II card), Smart Media card (SM card), Memory Stick (MS), MagicGate Memory Stick (MagicGate MS), Memory Stick Pro (MS Pro), MagicGate Memory Stick Pro (MagicGate MS Pro), Memory Stick Duo (MS Duo), MagicGate Memory Stick Duo (MagicGate MS Duo), Memory Stick Pro Duo (MS Pro Duo), and MagicGate Memory Stick Pro Duo (MagicGate MS Pro Duo).

5. The switching system of claim 2, wherein said input voltage is provided by an external device, which is electrically connected with said small memory card.

6. The switching system of claim 1, wherein the voltage level of said converting voltage is higher than which of said input voltage.

7. The switching system of claim 1, wherein the voltage level of said converting voltage is lower than which of said input voltage.

8. A small memory card having a switching system therein, comprising:
a controlled module used to control an operation of data reading and writing;
a data storage module used to store data; and
a switching voltage converting module used to convert an input voltage and provide said input voltage to said controlled module and said data storage module.

9. The small memory card of claim 8, wherein said controlled module includes a microprocessor.

10. The small memory card of claim 8, wherein said data storage module is a flash memory.

11. The small memory card of claim 8, wherein said data storage module is a micro drive.

12. The small memory card of claim 8, wherein the voltage level of said converting voltage is higher than which of said input voltage.

13. The small memory card of claim 12, wherein said switching voltage converting module having a Switching Boost-Up module, which includes one or the combination of the following components: a Pulse Width Modulation (PWM) Boost-Up circuit, a Pulse Frequency Modulation (PFM) Boost-Up circuit, and a Charge Pump Boost-Up circuit.

14. The small memory card of claim 8, wherein the voltage level of said converting voltage is lower than which of said input voltage.

15. The small memory card of claim 14, wherein said switching voltage converting module has a Switching Step-Down module, which includes one or the combination of the following: a Pulse Width Modulation (PWM) Step-Down circuit, and a Pulse Frequency Modulation (PFM) Boost-Up circuit.

16. A small memory card having a switching system therein, comprising:
a controlled module used to control data reading or writing;
a data storage module used to store data; and
a switching voltage boost-up module, wherein said switching voltage boost-up module is used to convert an input voltage to a boost-up voltage and provides said boost-up voltage to said controlled module and said data storage module.

17. The small memory card of claim 16, wherein said controlled module includes a microprocessor.

18. The small memory card of claim 1, wherein said data storage module is a flash memory.

19. The small memory card of claim 16, wherein said data storage module is a micro drive.

20. A small memory card having a switching system therein, comprising:
a controlled module used to control data reading or writing;
a data storage module used to store data; and
a switching voltage step-down module, wherein said switching voltage step-down module is used to convert an input voltage to a step-down voltage and provides said step-down voltage to said controlled module and said data storage module.

21. The small memory card of claim 20, wherein said controlled module includes a microprocessor.

22. The small memory card of claim 20, wherein said data storage module is a flash memory.

23. The small memory card of claim 20, wherein said data storage module is a micro drive.
